(19) United States
(12) Patent Application Publication
(10) Pub. No.: US 2004/0142519 A1
(43) Pub. Date: Jul. 22, 2004

(54) Methods of manufacturing a semiconductor device

(76) Inventor: Joung Ho Lee, Seoul (KR)

Correspondence Address: GROSSMAN & FLIGHT LLC, Suite 4220, 20 North Wacker Drive, Chicago, IL, 60606-6357, US

(21) Appl. No.: 10/746,836

(22) Filed: Dec. 26, 2003

(30) Foreign Application Priority Data
Dec. 30, 2002 (KR) 10-2002-0087482

(51) Int. Cl. H01L 21/336; H01L 21/8234; H01L 21/44

(52) U.S. Cl. 438/197; 438/592; 438/659; 438/660

(57) ABSTRACT

In a manufacturing method of a semiconductor device, before totally performing an annealing process for forming a silicide, reinforcing ions are implanted in a target of a thin metal layer formed on a source/drain so that the reinforcing ions naturally fill-in vacancy sites created in the substrate by the silicon atoms consumed during the silicide formation. When a substantial annealing process is subsequently performed, even though many silicon atoms move toward the metal atoms, the source/drain side semiconductor substrate has sufficient silicon atoms to prevent a shortage of the silicon atoms in the source/drain areas of the semiconductor substrate, and, thus, preventing the generation of defects such as voids, cracks and silicon spikes, etc., and improving the quality of the finished semiconductor device.

### CROSS-REFERENCE TO RELATED APPLICATION

The entire disclosure of Korean Patent Application No. 10-2002-0087482 filed on Dec. 30, 2002 is incorporated herein by reference in its entirety.

### FIELD OF THE DISCLOSURE

The present disclosure relates generally to semiconductor devices and, more particularly to, methods of manufacturing a semiconductor device.

### BACKGROUND

In the conventional system as shown in FIG. 1, a semiconductor device is manufactured by the following process. A gate insulating layer 2 and a poly gate 3 are formed on an active region of a semiconductor substrate 1. Ion implantation is then used to lightly dope impurities into a predetermined region 4a of a lightly doped drain (LDD) around the poly gate 3 as shown in FIG. 2. A spacer 5 is formed on the sidewalls of the poly gate 3. While using the spacer 5 as a mask, impurities are heavily doped into a predetermined region 6a of the source/drain around the poly gate 3 through an implantation. A high temperature annealing process is then performed on the semiconductor substrate 1 to induce the diffusion of the impurities implanted into the semiconductor substrate 1, thereby forming a finished LDD 4 and source/drain 6 as shown in FIG. 3. A sputtering process is performed so as to form a thin metal layer 7a on the front face of the semiconductor substrate (including on the source/drain 6 and on the poly gate 3). An annealing process is then used to induce a reaction of metal atoms forming the thin metal layer 7a with the silicon atoms forming the semiconductor substrate 1, to thereby form a silicide layer 7 on the surface of the source/drain 6 and the poly gate 3 as shown in FIG. 4.

U.S. Pat. No. 6,008,077 entitled “Method for fabricating semiconductor device”, and U.S. Pat. No. 6,586,162 entitled “Simple photo development step to form TiSiₓ, gate in DRAM process” describe a prior art approach to the formation of the silicide layer in detail.

In prior art systems as described above, the annealing process for the semiconductor substrate 1 is performed in order to form the finished silicide layer 7. Under the annealing process, the silicon atoms constituting the semiconductor substrate 1, (for example, the source/drain 6 areas of the semiconductor substrate 1), are quickly moved toward the metal atoms forming the thin metal layer 7a. The silicon atoms are, thus, bonded with the metal atoms.

However, when many silicon atoms forming the source/drain 6 areas of the semiconductor substrate 1 are moved toward the metal atoms to form the silicide layer 7, the source/drain areas of the semiconductor substrate 1 face a problem in that they are greatly consumed by the usage of the silicon atoms.

If the silicon atoms forming the source/drain 6 areas of the semiconductor substrate 1 are moved in sufficient quantities so that the corresponding semiconductor 1 is in want of silicon atoms, and if the finished silicide layer 7 is then formed through a series of phase transformations, the volume of the source/drain 6 areas of the semiconductor substrate 1 may be considerably shrunk due to the stress of the phase transformations. This shrinkage may result in various kinds of unnecessary defects such as voids, cracks, spikes, etc.

Such defects have a bad effect on the following post-processes, so that the quality of the finished semiconductor device cannot be maintained over a certain level without taking separate measures to remove the defects.

### BRIEF DESCRIPTION OF THE DRAWINGS

FIGS. 1 to 4 illustrate a prior art procedure for manufacturing a semiconductor device.

FIGS. 5 to 9 illustrate an example procedure for manufacturing a semiconductor device in accordance with the teachings of the present disclosure.

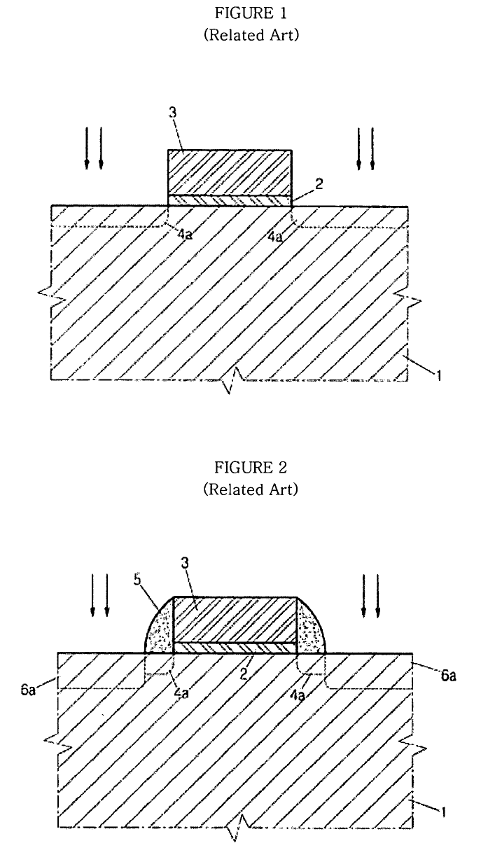

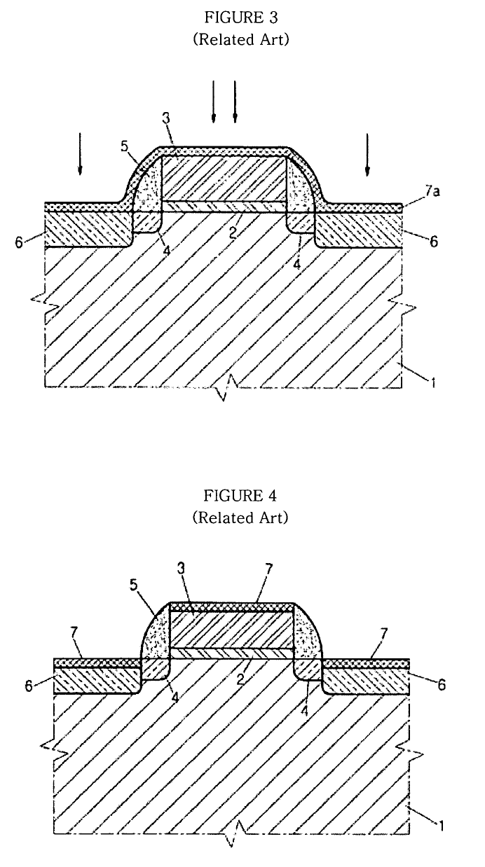

In the following description and drawings, the same reference numerals are used to designate the same or similar components, and so repetition of the description of the same or similar components will be omitted.

### DETAILED DESCRIPTION

Referring to FIG. 5, by selectively performing a thermal oxidation process, a low pressure chemical vapor deposition (CVD) process and the like, a base layer for a gate insulating layer is formed on a semiconductor substrate 11 and a poly silicon layer is formed on the base layer by the low pressure CVD process. Then, using a photolithography process, the base layer for the gate insulating layer and the poly silicon layer are patterned, so that a gate insulating layer 12 and a poly gate 13 are formed on an active region of the semiconductor substrate 11.

Then, impurities are ion-implanted at a low concentration into a predetermined region 14a of a lightly doped drain (LDD) around the poly gate 13 by performing an ion implantation process on the active region of the semiconductor substrate 11.

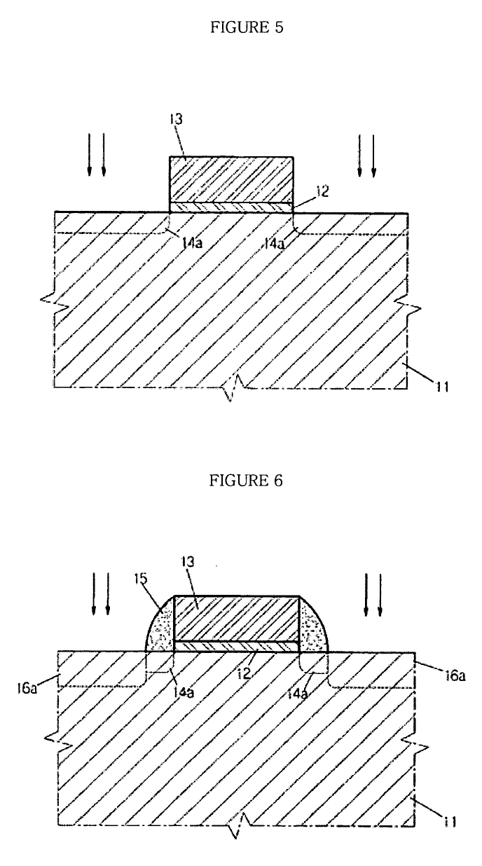

After the impurities have been lightly doped into the predetermined region 14a of the LDD through the above procedure, an insulating layer for a spacer covering the poly gate 13 is formed on the semiconductor substrate. The insulating layer may be formed by performing the low pressure CVD process and by performing a dry-etching process. The dry-etching process may be, for example, a reactive ion etching (RIE) process having an anisotropic etching feature. A spacer 15 is formed on the sidewalls of the poly gate 13 as shown in FIG. 6.

Subsequently, an ion implantation process is performed using the spacer 15 as a buffer mask so that a high concentration of impurities are ion-implanted into predetermined region(s) 16a of the source/drain around the poly gate 13.

After the impurities have been heavily doped into the predetermined region(s) 16a of the source/drain around the poly gate 13 through the above procedure, the semiconductor substrate 11 is moved into, for example, a diffusion furnace, in which a high temperature annealing process is performed so as to induce diffusion of the impurities implanted in the predetermined regions 14a and 16a of the LDD and source/drain, etc.

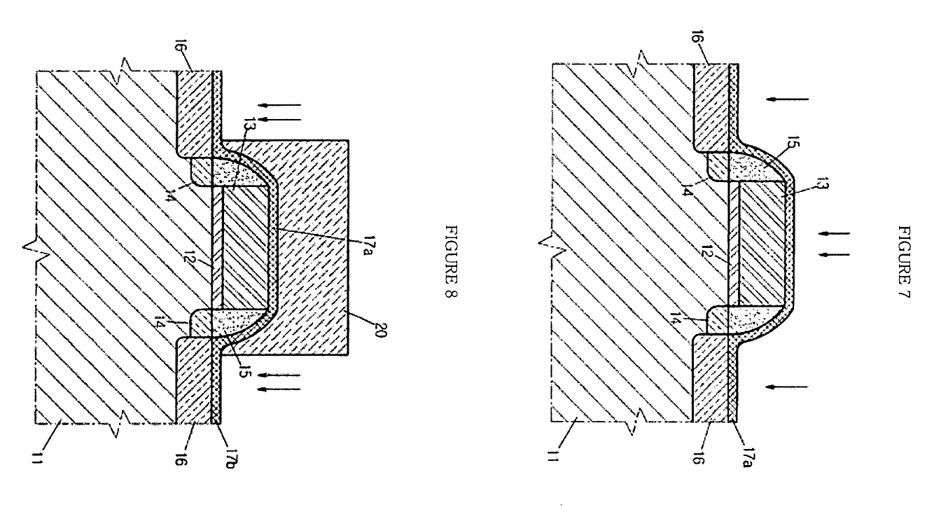

Finally, when the annealing process has been completed, as shown in FIG. 7, a completed LDD 14 and a source/drain 16 are formed on the active region of the semiconductor substrate 11.

By performing, for example, a sputtering process, a thin metal layer 17a, (for example, a Ti layer), is then formed on the semiconductor substrate 11, including on the poly gate 13 and on the source/drain 16.

Subsequently, a photoresist pattern 20 exposing the source/drain areas of the thin metal layer 17b around the poly gate 13 (that is, a photoresist pattern shielding the region of the poly gate 13 and spacer 15) is formed by coating the semiconductor substrate with a photoresist pattern and developing the photoresist pattern on the source/drain areas of the thin metal layer 17b. As a result, the photoresist pattern 20 stably shields the region of the poly gate 13 and the spacer 15, so that, when implanting reinforcing ions for the semiconductor substrate 11, the corresponding reinforcing ions are not implanted into the poly gate 13 and the spacer 15.

After the source/drain 16 areas of the thin metal layer 17b have been exposed through the procedure, an ion implantation process is preferably performed using the thin metal layer 17b as a target. As a result, reinforcing ions for the semiconductor substrate 11 are selectively added into the corresponding thin metal layer 17b. In this example, the reinforcing ions are silicon-based ions, for example, Si+ ions.

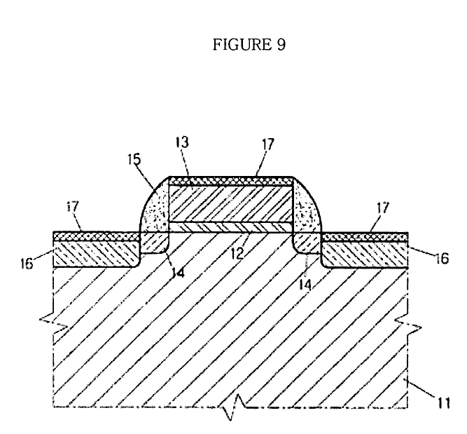

After removing the photoresist pattern 20, an annealing process is performed on the semiconductor substrate 11, so that the metal atoms forming the thin metal layer 17a and the silicon atoms forming the semiconductor substrate 11 are reacted with each other to thus form a silicide layer 17 (formed of, for example, SiTiₓ), on the surface of the source/drain 16 and the poly gate 13 as shown in FIG. 9.

As described above, in the formation system of the silicide layer 17, the silicon atoms forming, for example, the source/drain 16 areas of the semiconductor substrate 11 are quickly moved toward the metal atoms forming the metal thin layer 17b, (for example, a Ti layer). As a result, the silicon atoms are bound with the thin metal layer.

Since, before performing the total annealing process, an ion implantation process of the reinforcing ions for the semiconductor substrate (e.g., Si⁺ ions) is performed using the thin metal layer 17b formed on the source/drain 16 as a target, although a substantial annealing process is performed wherein the silicon atoms forming the source/drain 16 are moved fast toward the metal atoms forming the metal thin layer 17b, the source/drain 16 areas normally hold sufficient silicon atoms due to the additional supplement of the reinforcing ions. In other words, a shortage of the silicon atoms in the source/drain 16 areas of the semiconductor substrate 11 is prevented by previously supplementing the substrate 11 using an overdose implantation of silicon ions. As a result, the generation of defects such as voids, cracks, silicon spikes and the like is substantially prevented, and the quality of the finished semiconductor device is maintained above a certain level.

In performing the example process of FIGS. 5-9, the size of the dose of Si⁺ ions added to the source/drain 16 areas of the thin metal layer 17b is an important factor. This is because, if the dose of the Si⁺ ions is excessive as compared with that required to supplement the silicon atoms, unreacted Si⁺ ions may be unnecessarily left in the metal thin layer 17b, thereby causing another potential defect. On the other hand, if the dose of the Si⁺ ions is too small, the Si⁺ ions are not maintained at a sufficient level to successfully perform the supplement function for the silicon atoms.

Fully considering this fact, the dose of the Si⁺ ions added to the source/drain 6 regions of the thin metal layer 17b is preferably maintained at approximately 10¹⁴˜10¹⁵ atoms/cm². If the does is maintained at this level, the problems of unnecessarily leaving excess Si⁺ ions in the thin metal layer 17b and degradation of the supplement function of the Si⁺ ions for the silicon atoms are avoided.

Moreover, as with the size of the dose, in performing the example process of FIGS. 5-9, the implantation depth of the Si⁺ ions added to the source/drain 6 areas of the thin metal layer 17b is also an important factor. This is because, if the implantation depth of the Si⁺ ions is excessive such that it extends beyond the metal thin layer 17b and into the semiconductor substrate 11, unreacted Si⁺ ions may be unnecessarily left in the metal thin layer 17b, which may cause another potential defect. On the other hand, if the implantation depth of Si⁺ ions is too shallow, the reaction between the Si⁺ ions and the silicon atoms occurs only at the surface of the thin metal layer 17b, which may cause the supplement function of the Si⁺ ions to not be widely conducted.

Fully considering this fact, when the Si⁺ ions are implanted into the source/drain 16 areas of the thin metal layer 17b, the implantation energy is preferably maintained at approximately 5˜10 KeV. When the implantation energy is maintained in this range, the implantation depth of the Si⁺ ions into the metal thin layer 17b is substantially optimized. As a result, g the two problems of unnecessarily leaving excess Si⁺ ions in the thin metal layer 17b and unduly restricting the supplement function of the Si⁺ ions for the silicon atoms are avoided.

After the above described process is performed, subsequent processes may be successively performed (e.g., the formation processes for interlayer dielectric, contact hole and metallization), to stably complete the manufacturing process for the semiconductor device.

From the foregoing, persons of ordinary skill in the art will appreciate that, methods of manufacturing a semiconductor device are provided in which, before totally performing an annealing process for forming a silicide, an implanting process is additionally performed to a target of a thin metal layer to reinforce the ions for the semiconductor substrate. The reinforcing ions naturally supplement the vacancy of the silicon atoms consumed upon the silicide formation in the semiconductor substrate. Consequently, even though many silicon atoms move toward the metal atoms during a subsequent substantial annealing process, the source/drain regions of the semiconductor substrate normally has sufficient silicon atoms to avoid the defects associated with excessive depletion of the silicon atoms.

In the process of FIGS. 5-9, the silicon ions are implanted so as to supplement the silicon atoms, thus preventing a shortage of the silicon atoms in the source/drain regions of the semiconductor substrate, and, thus, preventing generation of defects such as voids, cracks and/or silicon spikes, etc., and improving the quality of the finished semiconductor device.

From the foregoing, persons of ordinary skill in the art will appreciate that the above disclosed methods and apparatus solve the abovementioned problems occurring in the prior art by, before totally performing an annealing process for forming a silicide, implanting reinforcing ions in a thin metal layer on a source/drain, so that the reinforcing ions naturally fill-in the vacancy created in the semiconductor substrate by the silicon atoms consumed during the silicide formation. Thus, even though many silicon atoms move toward the metal atoms owing to a substantial annealing process, the source/drain areas of the semiconductor substrate will have sufficient silicon atoms to avoid the defects associated with the prior art.

Further, the above disclosed methods and apparatus implant the silicon ions to supplement the silicon atoms, and prevent a shortage of the silicon atoms in the source/drain areas of the semiconductor substrate, thereby substantially preventing the generation of defects such as voids, cracks, or silicon spikes, and improving the quality of the completed semiconductor device. The disclosed methods of manufacturing a semiconductor device include: forming a gate insulating layer and a poly gate on a semiconductor substrate; forming a source/drain; forming a thin metal layer on the semiconductor substrate to cover the poly gate and the source/drain; selectively implanting reinforcing ions for the semiconductor substrate in the metal thin layer; and annealing the thin metal layer to form a silicide layer on the surface of the poly gate and the source/drain.

The reinforcing ions for the semiconductor substrate may be silicon based ions, and are preferably Si+ ions.

Preferably, the reinforcing ions for the semiconductor substrate are ion-implanted in a dose of approximately 10¹⁴˜1015 atoms/cm² by an ion implantation process with implantation energy of approximately 5˜10 KeV.

Preferably, the region including the poly gate is shielded before implanting the reinforcing ions for the semiconductor substrate in the metal thin layer.

Although certain example methods and apparatus have been described herein, the scope of coverage of this patent is not limited thereto. On the contrary, this patent covers all methods, apparatus and articles of manufacture fairly falling within the scope of the appended claims either literally or under the doctrine of equivalents.

What is claimed is:

1. 1. A method of manufacturing a semiconductor device, comprising:
forming a gate insulating layer and a poly gate on a semiconductor substrate;
forming a source/drain;
forming a thin metal layer on the poly gate and the source/drain;
selectively implanting reinforcing ions for the semiconductor substrate in the metal thin layer; and
annealing the thin metal layer to form a silicide layer on the poly gate and the source/drain.

2. A method as defined in claim 1, wherein the reinforcing ions are implanted in the thin metal layer on the source/drain.

3. A method as defined in claim 1, wherein the reinforcing ions are silicon-based ions.

4. A method as defined in claim 1, wherein the source/drain are formed by implanting impurity ions into a predetermined source/drain region near the poly gate.

5. A method as defined in claim 3, wherein the reinforcing ions are Si⁺ ions.

6. A method as defined in claim 1, wherein the reinforcing ions are ion-implanted in a dose of approximately 10¹⁴˜10¹⁵ atoms/cm².

7. A method as defined in claim 1, wherein the reinforcing ions are ion-implanted with implantation energy of approximately 5˜10 KeV.

8. A method as defined in claim 1, further comprising shielding the poly gate before implanting the reinforcing ions in the metal thin layer.

9. A method as defined in claim 8, wherein the poly gate is shielded by a photoresist pattern.
